(19) United States
(12) Patent Application Publication
(10) Pub. No.: US 2015/0061687 A1
(43) Pub. Date: Mar. 5, 2015

(54) BATTERY MANAGEMENT SYSTEM AND OPERATING METHOD THEREOF

(71) Applicant: Samsung SDI Co., Ltd., Yongin-si (KR)

(72) Inventor: Kyung-Sub SHIM, Yongin-si (KR)

(21) Appl. No.: 14/339,148

(22) Filed: Jul. 23, 2014

(30) Foreign Application Priority Data
Aug. 27, 2013 (KR) 10-2013-0101588

(51) Int. Cl. G01R 31/36

(52) U.S. Cl. CPC G01R 31/3679; G01R 31/3606
USPC 324/426

(57) ABSTRACT

A battery management system (BMS) is disclosed. In one aspect, the BMS includes a measuring unit, a pulse applying unit and a main controller unit (MCU). The measuring unit measures the voltage of a battery. The pulse applying unit applies a current pulse to the battery, the current pulse having a predetermined amplitude and period. The MCU calculates a polarization voltage based on the measured voltage and estimates a state of health (SOH) of the battery using a polarization voltage.

### CROSS-REFERENCE TO RELATED APPLICATIONS

This application claims priority to and the benefit of Korean Patent Application No. 10-2013-0101588, filed on Aug. 27, 2013, in the Korean Intellectual Property Office, the entire contents of which are incorporated herein by reference in their entirety.

### BACKGROUND

1. Field

The described technology generally relates to a battery management system (BMS) and an operating method thereof, and more particularly, to a BMS which can estimate a precise state of health (SOH) of a battery.

2. Description of the Related Technology

High-power secondary batteries which use a non-aqueous electrolyte with a high energy density have recently been developed. The standard large-capacity secondary battery also known as a rechargeable battery (hereinafter, referred to as a “battery”) includes a plurality of high-power secondary batteries connected in series. These batteries can be used in devices such as electric vehicles which require high power to drive the motors of the vehicles.

In the standard battery, the charging and discharging of the secondary batteries or battery cells must be controlled so that the battery is maintained in an appropriate operational state. To this end, the battery is typically augmented by a battery management system (BMS) for managing battery charging and discharging by measuring the voltage of each secondary battery cell and the voltage and current of the battery.

### SUMMARY OF CERTAIN INVENTIVE ASPECTS

One inventive aspect is a battery management system (BMS) and an operating method thereof which can estimate a more precise state of health (SOH) using a polarization voltage.

Another aspect is a BMS including a measuring unit configured to measure a voltage of a battery, a pulse applying unit configured to apply a current pulse to the battery, the current pulse having a predetermined amplitude and period, and a main controller unit (MCU) configured to calculate a polarization voltage based on the measured voltage and estimate an SOH of the battery using the polarization voltage.

The pulse applying unit may apply the current pulse to the battery when the battery is in an open circuit state.

The polarization voltage may be the difference between a first open circuit voltage (OCV) of the battery measured before the current pulse is applied and a second OCV of the battery measured after the current pulse is applied.

The MCU may include a memory and an SOH estimation unit configured to estimate the SOH of the battery using the first OCV and relationship data between the SOH and the polarization voltage. The first OCV may be stored in the memory.

The relationship data may be based on a proportional relationship between a loss capacity and the polarization voltage for each first OCV, a capacity required in an external device using the battery, and a minimum capacity.

The MCU may include a state of charge (SOC) estimation unit configured to estimate an SOC of the battery using the first OCV.

The current pulse may be an impulse current.

Another aspect is a method of operating a BMS, the method including measuring a first voltage of a battery, applying a current pulse having a predetermined amplitude and period to the battery, measuring a second voltage of the battery, generating a polarization voltage based on the first and second voltages, and estimating an SOH of the battery using the polarization voltage.

Another aspect is a battery system, including a battery, and a battery management system (BMS), wherein the BMS comprises a voltage sensor configured to measure a voltage of the battery, a pulse applying unit configured to apply a current pulse to the battery, and a controller configured to i) calculate a polarization voltage based at least in part on the measured voltage and ii) estimate a state of health (SOH) of the battery based at least in part on the polarization voltage.

The battery system may further comprise a switch configured to disconnect the battery from an external device. The pulse applying unit may be further configured to apply the current pulse to the battery when the battery is in an open circuit state. The polarization voltage may be defined as the difference between i) a first open circuit voltage (OCV) of the battery measured before the current pulse is applied and ii) a second OCV of the battery measured after the current pulse is applied.

The controller may include i) a memory and ii) an SOH estimation unit configured to estimate the SOH of the battery based at least in part on the first OCV and relationship data between the SOH and the polarization voltage, and wherein the first OCV and the relationship data are stored in the memory. The relationship data may be configured to be generated based on at least one of i) a proportional relationship between a loss in capacity and the polarization voltage for each first OCV, ii) a capacity required in an external device using the battery, or iii) a minimum capacity. The controller may include a state of charge (SOC) estimation unit configured to estimate an SOC of the battery based at least in part on the first OCV.

According to at least one embodiment, it is possible to more precisely estimate the SOH.

### BRIEF DESCRIPTION OF THE DRAWINGS

FIG. 1 is a diagram illustrating a battery according to an embodiment.

FIG. 2 is a diagram illustrating the relationship between the state of health (SOH) and a polarization voltage.

FIG. 3 is a block diagram schematically illustrating a battery management system (BMS) according to an embodiment.

FIG. 4 is a flowchart illustrating a method of operating the BMS according to an embodiment.

### DETAILED DESCRIPTION OF CERTAIN INVENTIVE EMBODIMENTS

The state of health (SOH) of a battery can be estimated using the state of charge (SOC) of the battery. The SOH should be precisely estimated in order to improve the efficiency of the battery over its lifetime. The SOC of the battery can be estimated by measuring the battery voltage. However, the measured voltage can vary from the actual voltage due to an error caused by a polarization voltage generated by the charging or discharging process.

Exemplary embodiments will now be described more fully hereinafter with reference to the accompanying drawings. However, the described technology may be embodied in different forms and should not be construed as limited to the embodiments set forth herein. Rather, these embodiments are provided so that this disclosure will be thorough and complete and will fully convey the scope of the described technology to those skilled in the art.

In the drawings, dimensions may be exaggerated for clarity of illustration. It will be understood that when an element is referred to as being “between” two elements, it can be the only element between the two elements, or one or more intervening elements may also be present. Like reference numerals refer to like elements throughout the specification.

When a first element is described as being connected to a second element, the first element may be directly connected to the second element or may be indirectly connected to the second element via a third element. Further, some of the elements that are not essential to the complete understanding of the described technology are omitted for clarity. The term “connected” as used herein includes the term “electrically connected.”

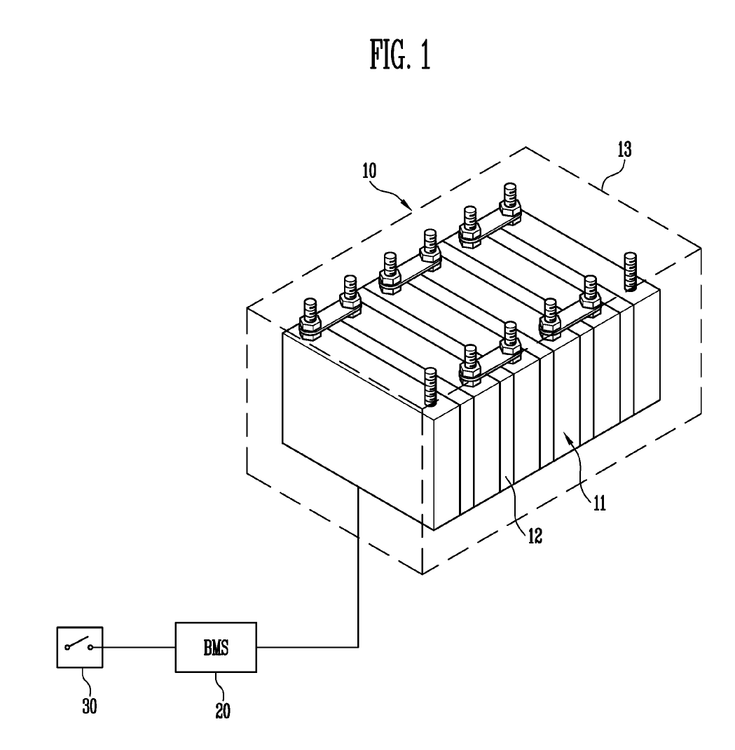

FIG. 1 is a diagram illustrating a battery according to an embodiment.

Referring to FIG. 1, the battery 10 is a large-capacity battery module in which a plurality of secondary batteries (or battery cells) 11 are consecutively arranged at a predetermined interval. The battery 10 may include a housing 13 in which the secondary batteries 11 are disposed and a cooling medium is circulated. A battery management system (BMS) 20 is connected to the battery 10 and is configured to manage the charging and discharging of the battery 10.

Battery barriers 12 are respectively disposed between the secondary batteries 11 and at the outermost sides of the secondary batteries 11. The battery barriers 12 allow air to be circulated between the secondary batteries 11 for temperature control. The battery barriers also maintain the space between the secondary batteries 11 and support the side surfaces of each secondary battery 11.

Although it has been illustrated in FIG. 1 that the secondary battery 11 has a substantially rectangular shape, it will be apparent to those of ordinary skill in that art that the secondary battery 11 may have a substantially cylindrical structure or any other shape.

The BMS 20 measures current and voltage of each secondary battery 11 in the battery 10 and manages the battery based on the detected currents and voltages.

The BMS 20 receives data from a current sensor (not shown) and a voltage sensor (not shown) which are installed in the battery 10.

The current sensor is connected to any one of positive and negative terminals of the battery 10 and measures the charging and discharging current of the battery 10. The voltage sensor is connected to the positive and negative terminals of the battery 10 and measures the terminal voltage of the battery 10.

A switch 30 is in a closed state during a charging/discharging period in which the charging or discharging of the battery 10 is performed to connect the battery 10 to an external device. The switch 30 is in an open state during a non-active period in which the charging or discharging of the battery 10 is not performed to disconnect the battery 10 from the external device.

During the non-active period in which the charging or discharging of the battery 10 is not performed, an open circuit voltage (hereinafter, referred to as an OCV) is measured by the voltage sensor since the battery 10 is in an open circuit state.

The BMS 20 stores predetermined data about the relationship between of the state of charge (SOC) and the OCV of the battery 10 in a table. Consequently, the SOC can be estimated from the OCV measured in the voltage sensor.

A state of health (SOH) may be determined by comparing the current capacity of the battery 10 with the capacity required in a system using the battery 10. If the current SOC is greater than the capacity required in the system, the SOH is defined as 100. If the current SOC is less than the minimum capacity required in the system, the SOH is defined as 0.

If current is applied to charge or discharge the battery 10, a polarization voltage is generated which is proportional to the applied current. The described technology provides a method of estimating the SOH of the battery 10 using the proportional relationship between the polarization voltage and the SOH.

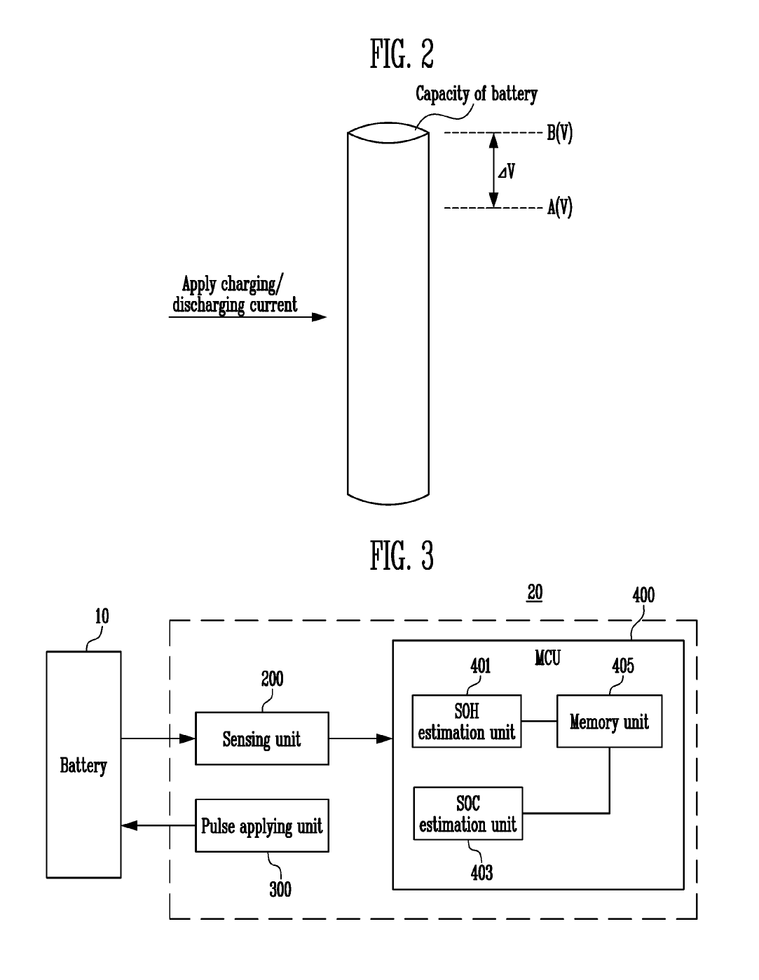

FIG. 2 is a diagram illustrating the relationship between the SOH and the polarization voltage.

Referring to FIG. 2, the capacity of the battery 10 corresponds to a voltage A measured in an OCV state. The battery 10 first reaches a charging capacity corresponding to a voltage B due to the polarization voltage generated by the current applied to the battery 10.

That is, the battery 10 first reaches a charging upper limit voltage corresponding to the polarization voltage when charging of the battery 10 and consequently a loss in capacity occurs corresponding to the voltage which does not charge the battery 10. Accordingly, the actual charging capacity of the battery 10 is decreased. Similarly, the battery 10 first reaches a discharging lower limit voltage corresponding to the polarization voltage when discharging of the battery 10 and consequently a loss in capacity occurs corresponding to the voltage which does not discharge the battery 10. Accordingly, the actual discharging capacity of the battery 10 is also decreased. Thus, the described technology provides a method of estimating the SOH of a battery using the relationship between the loss in capacity and the SOH based on the polarization voltage.

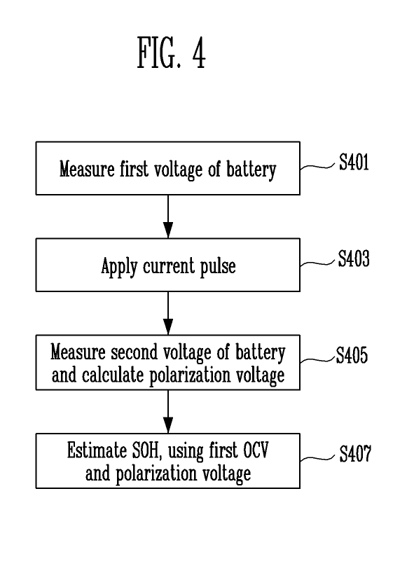

FIG. 3 is a block diagram schematically illustrating the BMS according to an embodiment.

As shown in FIG. 3, the BMS 20 includes a sensing unit (or measuring unit) 200, a pulse applying unit 300 and a main controller unit (MCU) (or a controller) 400.

The sensing unit 200 measures the voltage of the battery 10 using the voltage sensor and provides the measured voltage to the MCU 400.

The pulse applying unit 300 applies a current pulse having a predetermined amplitude and period to the battery 10 to generate a polarization voltage. The current pulse may be generated to have various different widths, amplitudes, periods, etc.

For example, the current pulse may be a transient impulse current with no periodicity, which rapidly rises to a maximum value and rapidly drops to 0. The pulse applying unit 300 may generate the polarization voltage in the battery 10 by applying the impulse current to the battery 10.

According to the present embodiment, the pulse applying unit 300 applies the current pulse to the battery 10 when the battery 10 is in the open circuit state. The polarization voltage is generated when the battery 10 is stabilized in the open circuit state so that a precise SOH can be estimated.

According to the present embodiment, the MCU 400 may include an SOH estimation unit 401, an SOC estimation unit 403 and a memory unit (or memory) 405.

The SOH estimation unit 401 estimates the SOH of the battery 10 using a polarization voltage generated by a current pulse.

Here, the polarization voltage is the difference between a first OCV of the battery 10 measured by the sensing unit 200 before the current pulse is applied and a second OCV of the battery 10 measured by the sensing unit 200 after the current pulse is applied.

For example, in the case where the first OCV of the battery 10 measured before the current pulse is applied is about 3.0V and the second OCV of the battery 10 measured after the current pulse is applied is about 3.1V, the polarization voltage is be about 0.1V.

According to the present embodiment, the SOH estimation unit 401 estimates the SOH of the battery 10 using a first OCV stored in the memory unit 405 and relationship data between the SOH and the polarization voltage.

Here, the relationship data may be relationship data for the SOH calculated according to the proportional relationship between a loss in capacity and the polarization voltage for each first OCV, the capacity required by the external device using the battery, and the minimum capacity. The relationship data may be obtained by mapping an SOH estimated based on the polarization voltage measured for each first OCV to a table.

For example, in the case where the loss in capacity for a polarization voltage of about 0.2V is about 0.5 KW when the required capacity is about 3 KW, the minimum capacity is about 2 KW, and the first OCV is about 3.3V, the SOH may be determined to be about 50% according to the proportional relationship. Accordingly, the relationship data can be stored in the memory unit 405 to reflect that the SOH is about 50% when the first OCV is about 3.3V and the polarization voltage is about 0.2V. The relationship data between the polarization voltage and the SOH may have various different values according to the capacity and usage environment of the battery 10. The relationship data may be predetermined and stored based on a user's experiments.

In the conventional art, it is difficult to measure the SOH and the estimation of the SOH is time intensive. Hence, a continuously accumulated value was required to be stored.

On the other hand, in the described technology, the SOH is estimated using the predetermined relationship data stored in the memory unit 405. Thus, the SOH can be easily estimated by measuring the first OCV and the polarization voltage.

The SOC estimation unit 403 estimates the SOC using the first OCV. For example, the SOC estimation unit 403 may estimate the SOC using the predetermined relationship data between the first OCV and the SOC stored in the memory unit 405.

FIG. 4 is a flowchart illustrating a method of operating the BMS according to an embodiment.

In some embodiments, the FIG. 4 procedure is implemented in a conventional programming language, such as C or C++ or another suitable programming language. The program can be stored on a computer accessible storage medium of the BMS 20, for example, the memory unit 405. In certain embodiments, the storage medium includes a random access memory (RAM), hard disks, floppy disks, digital video devices, compact discs, video discs, and/or other optical storage mediums, etc. The program may be stored in a processor. The processor can have a configuration based on, for example, i) an advanced RISC machine (ARM) microcontroller and ii) Intel Corporation's microprocessors (e.g., the Pentium family microprocessors). In certain embodiments, the processor is implemented with a variety of computer platforms using a single chip or multichip microprocessors, digital signal processors, embedded microprocessors, microcontrollers, etc. In another embodiment, the processor is implemented with a wide range of operating systems such as Unix, Linux, Microsoft DOS, Microsoft Windows 7/Vista/2000/9x/ME/XP, Macintosh OS, OS/2, Android, iOS and the like. In another embodiment, at least part of the procedure can be implemented with embedded software. Depending on the embodiment, additional states may be added, others removed, or the order of the states changed in FIG. 4.

The sensing unit 200 measures a first voltage of the battery (S401). In this case, the first voltage may be a first OCV measured when the battery is stabilized in the open state.

The pulse applying unit 300 applies a current pulse to the battery (S403). According to the present embodiment, the pulse applying unit 300 applies the current pulse to the battery when the battery is in the open state.

Subsequently, the sensing unit 200 measures a second voltage of the battery after the current pulse is applied to the battery and calculates a polarization voltage based on the measured second voltage (S405). Here, the second voltage may be a second OCV measured when the battery is in the open state and the polarization voltage is the difference between the first and second voltages.

Finally, the SOH estimation unit 403 estimates the SOH of the battery using the polarization voltage (S407). Specifically, the SOH estimation unit 403 may estimate the SOH of the battery using the first OCV stored in the memory unit 405 and the relationship data between the SOH and the polarization voltage.

Exemplary embodiments have been disclosed herein, and although specific terms are employed, they are used and are to be interpreted in a generic and descriptive sense only and not for the purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless specifically indicated otherwise. Accordingly, it will be understood by those of skill in the art that various changes in form and details may be made without departing from the spirit and scope of the present invention as set forth in the following claims.

What is claimed is:

1. A battery management system (BMS), comprising:
a measuring unit configured to measure a voltage of a battery;
a pulse applying unit configured to apply a current pulse to the battery, wherein the current pulse has a predetermined amplitude and period; and
a main controller unit (MCU) configured to i) calculate a polarization voltage based at least in part on the measured voltage and ii) estimate a state of health (SOH) of the battery based at least in part on the polarization voltage.

2. The BMS of claim 1, wherein the pulse applying unit is further configured to apply the current pulse to the battery when the battery is in an open circuit state.

3. The BMS of claim 2, wherein the polarization voltage is defined as the difference between i) a first open circuit voltage (OCV) of the battery measured before the current pulse is applied and ii) a second OCV of the battery measured after the current pulse is applied.

4. The BMS of claim 3, wherein the MCU includes i) a memory and ii) an SOH estimation unit configured to estimate the SOH of the battery based at least in part on the first OCV and relationship data between the SOH and the polarization voltage, wherein the first OCV and the relationship data are stored in the memory.

5. The BMS of claim 4, wherein the relationship data is configured to be generated based on at least one of i) a proportional relationship between a loss in capacity and the polarization voltage for each first OCV, ii) a capacity required in an external device using the battery, or iii) a minimum capacity.

6. The BMS of claim 3, wherein the MCU includes a state of charge (SOC) estimation unit configured to estimate an SOC of the battery based at least in part on the first OCV.

7. The BMS of claim 1, wherein the current pulse is an impulse current.

8. A method of operating a battery management system (BMS), comprising:
measuring a first voltage of a battery;
applying a current pulse, having a predetermined amplitude and period, to the battery;
measuring a second voltage of the battery;
calculating a polarization voltage based at least in part on the first and second voltages; and
estimating a state of health (SOH) of the battery based at least in part on the polarization voltage.

9. The method of claim 8, wherein the current pulse is applied to the battery when the battery is in an open circuit state.

10. The method of claim 8, wherein the polarization voltage is defined as the difference between the first and second voltages, wherein the first voltage is measured before the current pulse is applied, wherein the second voltage is measured after the current pulse is applied, and wherein the first and second voltages are open circuit voltages (OCV) of the battery.

11. The method of claim 10, wherein the estimating is performed based at least in part on the first OCV and relationship data between the SOH and the polarization voltage.

12. The method of claim 11, wherein the relationship data is generated based on at least one of i) a proportional relationship between a loss in capacity and the polarization voltage for each first OCV, ii) a capacity required in an external device using the battery, or iii) a minimum capacity.

13. The method of claim 8, wherein the current pulse is an impulse current.

14. A battery system, comprising:
a battery; and
a battery management system (BMS), wherein the BMS comprises:
a voltage sensor configured to measure a voltage of the battery;
a pulse applying unit configured to apply a current pulse to the battery; and
a controller configured to i) calculate a polarization voltage based at least in part on the measured voltage and ii) estimate a state of health (SOH) of the battery based at least in part on the polarization voltage.

15. The battery system of claim 14, further comprising a switch configured to disconnect the battery from an external device.

16. The battery system of claim 14, wherein the pulse applying unit is further configured to apply the current pulse to the battery when the battery is in an open circuit state.

17. The battery system of claim 16, wherein the polarization voltage is defined as the difference between i) a first open circuit voltage (OCV) of the battery measured before the current pulse is applied and ii) a second OCV of the battery measured after the current pulse is applied.

18. The battery system of claim 17, wherein the controller includes i) a memory and ii) an SOH estimation unit configured to estimate the SOH of the battery based at least in part on the first OCV and relationship data between the SOH and the polarization voltage, and wherein the first OCV and the relationship data are stored in the memory.

19. The battery system of claim 18, wherein the relationship data is configured to be generated based on at least one of i) a proportional relationship between a loss in capacity and the polarization voltage for each first OCV, ii) a capacity required in an external device using the battery, or iii) a minimum capacity.

20. The battery system of claim 17, wherein the controller includes a state of charge (SOC) estimation unit configured to estimate an SOC of the battery based at least in part on the first OCV.
